(19) United States
(12) Patent Application Publication
(10) Pub. No.: US 2004/0096025 A1
(43) Pub. Date: May 20, 2004

(54) Method and system for a programmable diphase digital phase lock loop

(76) Inventor: Michael E. Rupp, Amherst, NY (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/301,170

(22) Filed: Nov. 20, 2002

(51) Int. Cl. H03D 3/24

(52) U.S. Cl. 375/376

(57) ABSTRACT

A method and system is provided for a programmable diphase digital phase lock loop (PDDPLL). The PDDPLL has an input to receive a diphase input signal and an output to provide an output signal that is synchronized to the data edges of the diphase input signal. The system includes a configuration component coupled to the PDDPLL to program selected parameters of the PDDPLL output signal. The PDDPLL may locate two consecutive data edges of the diphase input signal that are a programmed bit time apart to determine the positions of the data edges of a continuous diphase input signal. The PDDPLL may locate a beginning of a packet transmission and cause the programmable diphase digital phase lock loop to output a signal that is synchronized to the data edges of the diphase input signal during the packet transmission and free runs at a programmed rate between packet transmissions.

### BACKGROUND

1. Field

Embodiments of the invention relate to the field of phase lock loop circuitry, and more specifically to a programmable diphase digital phase lock loop.

2. Background Information and Description of Related Art

A conventional diphase digital phase lock loop can provide an output signal which is synchronized to a diphase signal applied to an input of the phase lock loop. However, the period and all other parameters of the output signal are set in the hardware of the conventional diphase digital phase lock loop and cannot be changed without a redesign. This precludes rapid prototyping, rapid integration into new designs, and easy modification of the signal parameters in the field to meet specific user needs.

### BRIEF DESCRIPTION OF DRAWINGS

The invention may best be understood by referring to the following description and accompanying drawings that are used to illustrate embodiments of the invention. In the drawings:

FIG. 1 is a block diagram illustrating one generalized embodiment of a system incorporating the invention.

FIG. 2 is a block diagram illustrating use of a programmable diphase digital phase lock loop in a telephony application according to one embodiment of the invention.

FIG. 3a is a graph including waveforms illustrating the operation of a diphase digital phase lock loop with a continuous diphase input signal.

FIG. 3b is a graph including waveforms illustrating the operation of a diphase digital phase lock loop with an intermittent diphase input signal.

FIG. 4a is a graph including waveforms illustrating selected programmed parameters and windows for the operation of a diphase digital phase lock loop with a continuous diphase input signal.

FIG. 4b is a graph including waveforms illustrating selected programmed parameters and windows for the operation of a diphase digital phase lock loop with an intermittent diphase input signal.

FIG. 5 is a graph including waveforms illustrating a method according to one embodiment of the invention for adjusting the period of the output signal when the period is not an integer multiple of the period of the base clock signal.

FIGS. 6-9 are schematic diagrams illustrating one implementation of a system with a programmable diphase digital phase lock loop in greater detail according to one embodiment of the invention.

FIG. 10 is a flow diagram illustrating a method according to an embodiment of the invention.

FIG. 11 is a flow diagram illustrating a method according to an embodiment of the invention.

### DETAILED DESCRIPTION

Embodiments of a system and method for a programmable diphase digital phase lock loop are described. In the following description, numerous specific details are set forth. However, it is understood that embodiments of the invention may be practiced without these specific details. In other instances, well-known circuits, structures and techniques have not been shown in detail in order not to obscure the understanding of this description.

Reference throughout this specification to “one embodiment” or “an embodiment” means that a particular feature, structure, or characteristic described in connection with the embodiment is included in at least one embodiment of the invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

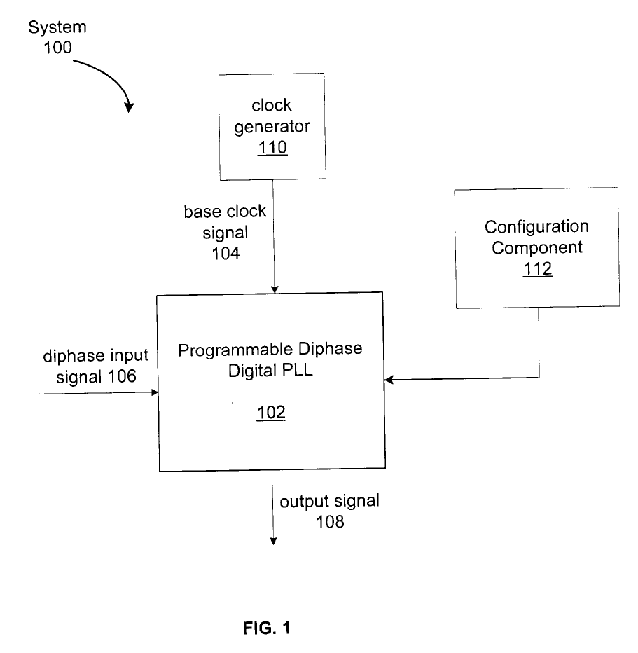

Referring to FIG. 1, a block diagram illustrates a system 100 according to one embodiment of the invention. Those of ordinary skill in the art will appreciate that the system 100 may include more components than those shown in FIG. 1. However, it is not necessary that all of these generally conventional components be shown in order to disclose an illustrative embodiment for practicing the invention.

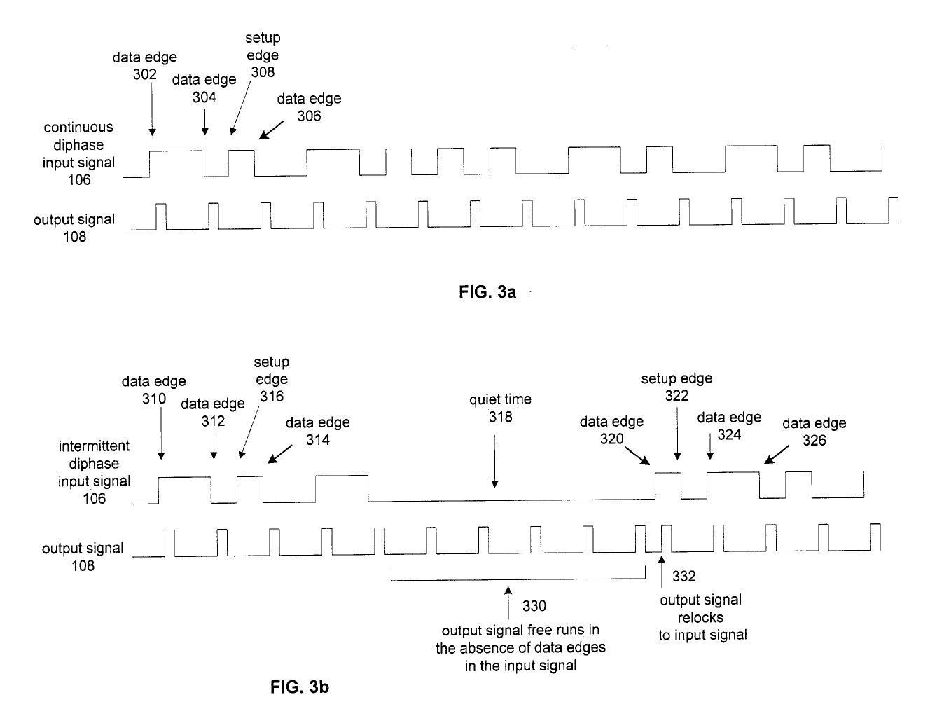

System 100 includes a programmable diphase digital phase lock loop (PDDPLL) 102. The PDDPLL 102 has an input to receive a diphase input signal 106. The diphase input signal 106 may be a continuous signal, as shown in FIG. 3a, or an intermittent signal, as shown in FIG. 3b. System 100 has a clock generator 10 to generate a base clock signal 104 to serve as the system clock for the PDDPLL 102. The clock generator 110 may be separate from the PDDPLL 102, as shown in FIG. 1, or the clock generator 110 may be integrated with the PDDPLL 102. The PDDPLL 102 has an output to provide an output signal 108 that is synchronized with the data edges of the diphase input signal 106. In one embodiment, the PDDPLL 102 provides an output signal that free runs at a programmed rate in the absence of any data edges in the diphase input signal for a programmed period of time.

A configuration component 112 is coupled to the PDDPLL 102 to program selected parameters of the output signal. The configuration component 112 writes parameters to the PDDPLL 102 that describe the input signal 106. These parameters allow the PDDPLL 102 to provide an output signal 108 that is synchronized with the data edges of the diphase input signal 106. In one embodiment, the configuration component 112 includes a microprocessor to program selected parameters of the output signal. The microprocessor may contain a program which causes the PDDPLL 102 to provide an output signal synchronized to the data edges of the diphase input signal. The program may also cause the PDDPLL to provide an output signal that free runs at a programmed rate in the absence of data edges in the input signal. Alternatively, the configuring component 112 may include combinatorial or sequential logic coupled to the PDDPLL 102 with changeable coded values used to configure the PDDPLL 102.

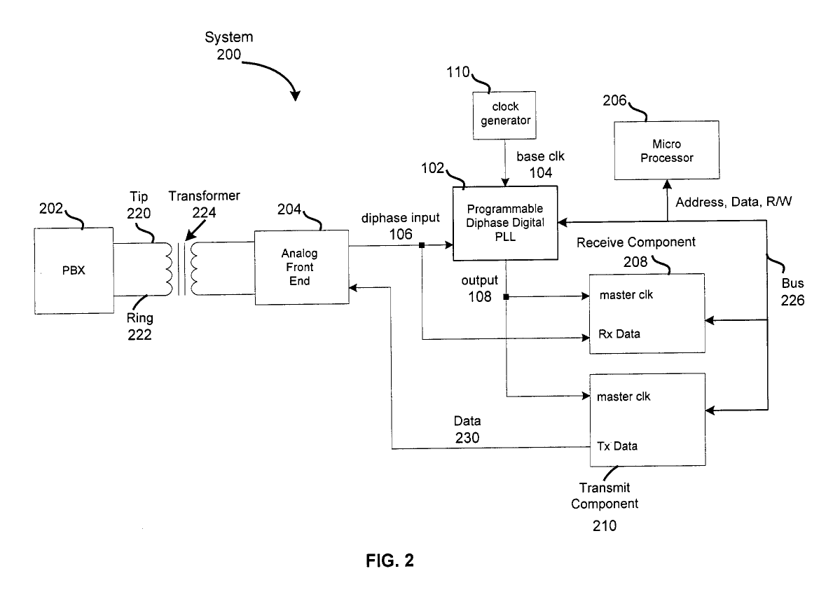

FIG. 2 is a block diagram illustrating use of a programmable diphase digital phase lock loop in a telephony application according to one embodiment of the invention. A telephony switch or PBX 202 has tip 220 and ring 222 signal lines coupled through a transformer 224 to an analog front end component 204, which functions as an analog to digital converter. An output of the analog front end 204 provides the diphase input signal 106 to the PDDPLL 102. The output signal 108 from the PDDPLL 102 is input into a receive component 208 as a master clock input. The diphase input signal 106 from the analog front end 204 is input into the receive component 208 as a data input. The output signal 108 from the PDDPLL 102 tells receive component 208 when to look at the diphase input signal 106 during each period of the input signal 106 for the purpose of extracting data from the input signal 106. The output signal 108 also contains information on the data rate of the input signal 106.

A microprocessor 206 is coupled via a bus 226 to the PDDPLL 102 and to the receive component 208. Receive component 208 converts the serial data it receives from the input signal 106 to parallel data for use by microprocessor 206. Microprocessor 206 uses the parallel data to determine the various telephony operations commanded by PBX 202, for example, an indicator to light up on a particular telephone set or a particular set to ring. Since the telephone set is emulated by microprocessor 206, no physical telephone set is shown in FIG. 2.

System 200 also includes a transmit component 210, which is coupled to the microprocessor 206 via the bus 226. The output signal 108 from the PDDPLL 102 is input into the transmit component 210 as the master clock input. A data output 230 from the transmit component 210 is sent to the analog front end 204. Transmit component 210 takes the parallel data from the microprocessor 206 and converts the parallel data to serial data for transmission to the PBX 202. This data tells PBX 202 about telenhony events which have occurred, for example, a button on a particular telephone set was pushed or when a set is off hook. The output signal 108 from the PDDPLL 102 controls the rate at which data is transmitted from transmit component 210 to PBX 202.

FIG. 3a is a graph including waveforms illustrating the operation of a diphase digital phase lock loop with a continuous diphase input signal. Diphase is an encoding scheme for serial digital data. Each bit is set at a predetermined interval. The value of the bit is not determined by the voltage level on the line but instead is determined by the direction of the voltage transition that occurs at every bit time. For example, a one may be encoded by a rising edge and a zero by a falling edge. In this case, in order to encode two consecutive bits with the same value, a non-bit time transition, also known as a setup edge, is needed in between the two data edges to set up the bit-time transition. Another diphase encoding scheme, known as differential diphase, encodes a zero as an edge that is in the same direction as the previous data edge and a one as an opposite edge. Even though the encoding schemes for these diphase methods may be slightly different, they all have a data edge at each bit time and setup edges as necessary.

FIG. 3a shows an example of a continuous diphase input signal, which is a signal that continuously transmits data. Suppose in this example that a zero is encoded by a rising edge and a one by a falling edge. In this case, data edge 302 is encoding a zero, while data edges 304 and 306 are both encoding a one. Data edges 302, 304, and 306 are all bit time transitions. Since the consecutive bits encoded at 304 and 306 are of the same value (one), there needs to be a non-bit time transition 308 (rising edge) after transition 304 (falling edge) to set up the transition 306 (also a falling edge). This non-bit time transition or setup edge 308 typically occurs at one-half the time between the data edges or bit times. The PDDPLL 102 finds the positions of the data edges of the diphase input signal 106 and outputs a signal 108 that is synchronized to these data edges. An example of the output signal 108 for a continuous diphase input signal 106 is shown in FIG. 3a.

FIG. 3b shows an example of an intermittent diphase input signal, which is a signal that has breaks in the transmission due to transmitting data in packets. During these breaks, there are no data edges in the input signal, as shown at 318. The output signal 108 from the PDDPLL 102 synchronizes to the data edges of the diphase input signal 106 when there are data edges present in the input signal 106. In the absence of any data edges in the input signal 106 for a programmed period of time (a break in the input signal), the PDDPLL 102 outputs a signal that free runs at a programmed rate, as shown at 330. When the break in the input signal ends, the output signal resynchronizes to the data edges of the input signal. An example output signal 108 for an intermittent diphase input signal is shown in FIG. 3b.

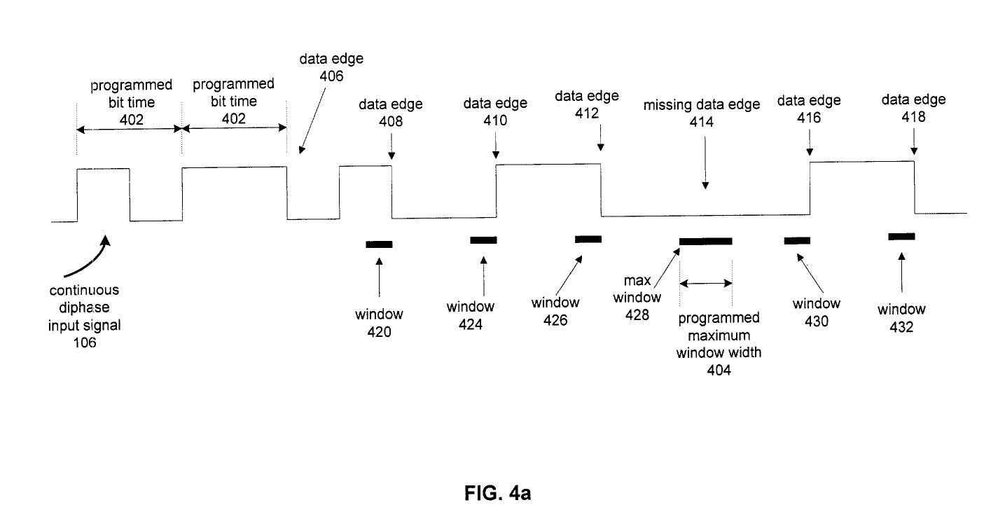

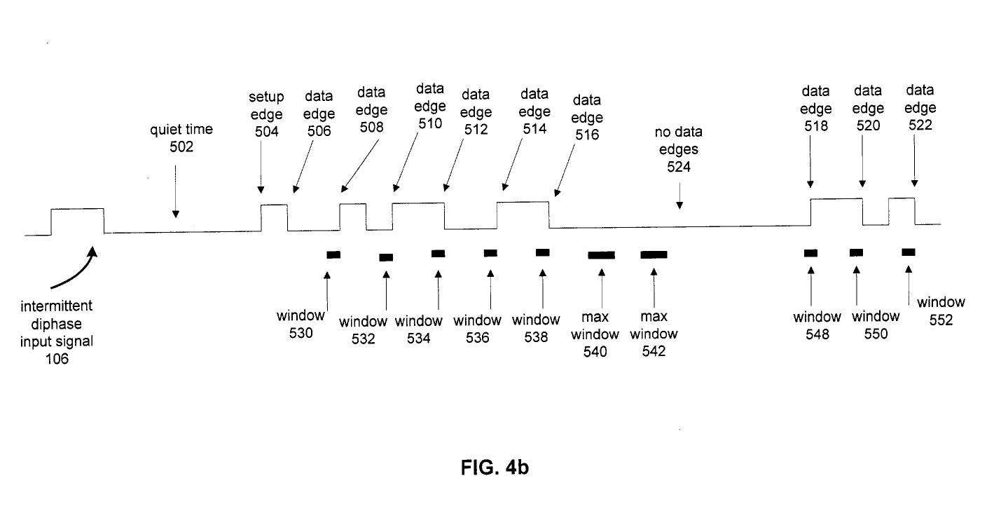

FIG. 4a shows the continuous diphase input signal with selected parameters in greater detail. The PDDPLL 102 sorts out the data edges from the setup edges in the input signal 106. This is done by finding two consecutive edge transitions that are approximately a programmed bit time apart. Since the two edges are the bit time apart, they are data edges. When the PDDPLL 102 finds the second consecutive data edge, for example data edge 406, a time window, such as 420, is opened to capture the next data edge. The window is centered around where the next data edge 408 is expected. In one embodiment, the window has a maximum window width equal to the maximum expected jitter. When an edge is detected in the time window, a bit clock output signal 108 is created. The window closes when an edge is detected or when the maximum window width is reached. Then, a next window, such as 424, is opened where the next data edge 410 is expected. A series of windows, such as 426, 428, 430, and 432, are opened to capture data edges, such as 412, 416, and 418. This creates a bit clock output signal 108 that is locked, or synchronized, to the bit time transitions, or data edges, of the diphase input signal 106. Any transitions outside the windows are ignored. If there is a missing data edge in the input signal, such as at 414, the window 428 will close when the maximum window width is reached, and a next window 430 will be opened that is centered around where the next data edge 416 is expected. The bit time and the maximum window width are parameters that are programmed by the configuration component 112 into the PDDPLL 102.

FIG. 4b shows the intermittent diphase input signal with selected parameters in greater detail. Unlike the continuous diphase input signal, the intermittent diphase input signal has breaks in the transmission due to transmitting data in packets. Therefore, the PDDPLL 102 first locates the start of a packet. This is done by waiting until there is quiet time, such 502, when there are no data edges in the input signal 106. Then, the PDDPLL 102 searches for the first transition after the quiet time. Whether this transition is a setup edge or a data edge may be programmed. The first data edge 506 starts the bit clock output signal. A time window, such as 530, is opened and centered around when the next data edge 508 is expected. When an edge is detected in the window, a bit clock is created. The window closes when an edge is detected or when the maximum window width is reached. Then, a next window, such as 532, is opened and centered around where the next data edge 510 is expected. A series of windows such as 534, 536, 538, are opened to capture data edges, such as 512, 514, and 516. This creates a bit clock output signal 108 that is locked, or synchronized, to the bit time transitions, or data edges, of the diphase input signal 106. Any transitions outside the windows are ignored. When a packet ends, there is a break in the input signal 106. When the PDDPLL 102 detects a programmed number of missing data edges or programmed minimum quiet time, the PDDPLL 102 outputs a signal that free runs at a programmed rate. For example, as shown in FIG. 4b, suppose the programmed number of missing data edges is two. Therefore, after two consecutive windows, 540 and 542, without data edges, the PDDPLL 102 outputs a signal 108 that free runs at a programmed frequency. Then, the PDDPLL 102 searches for the next transition or edge, signifying the start of a new packet transmission. When this first transition occurs, such as at 518, the PDDPLL 102 begins opening a series of windows again, as before, and locks or synchronizes to the data edges of the input signal. The bit time, the maximum window width, and the minimum quiet time are parameters that are programmed by the configuration component 112 into the PDDPLL 102.

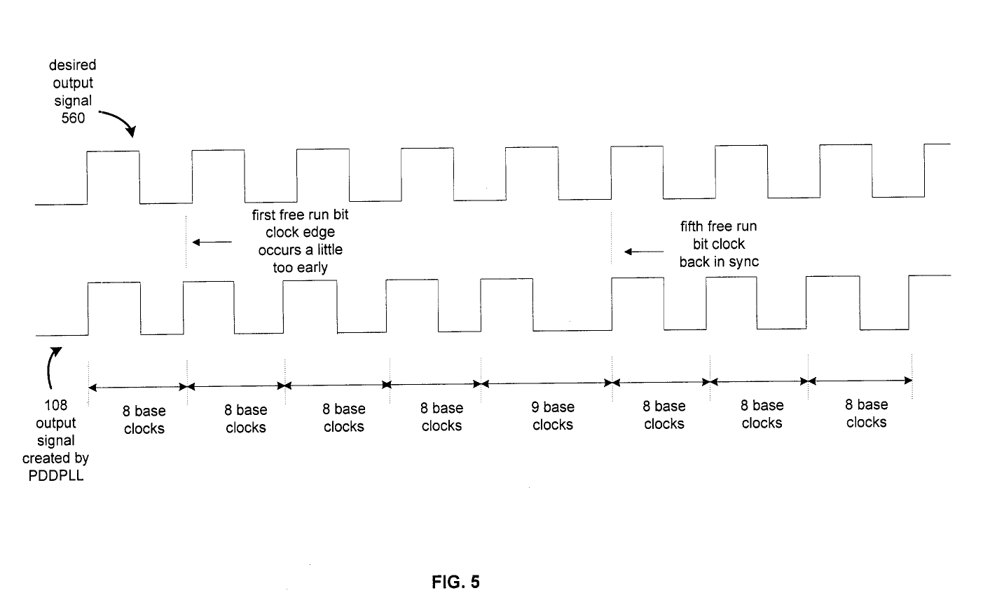

FIG. 5 is a graph including waveforms illustrating a method for adjusting the period of the free-running output signal when it is not an integer multiple of that of the base clock signal according to one embodiment of the invention. Parameters that are programmed into the PDDPLL 102 are integral multiples of the PDDPLL base clock 104. When the output signal 108 free runs during the absence of data edges of the diphase input signal 106, the period of the output signal will be an integral multiple of the base clock signal 104. If an output signal 108 is desired that has a period that is not an integral multiple of the PDDPLL base clock 104, an adjustment is made to the period of the output signal 108 to bring it back to the desired period. To do this adjustment, the desired period of the output signal is divided by the period of the base clock signal to obtain a result in the form of a whole number W and fractional remainder, X/Y. The whole number W is the basic, unadjusted number of base clock periods in each bit clock period. The denominator of the fractional remainder Y defines the number of bit clocks contained in an adjustment set. The numerator of the fractional remainder X specifies how many bit clocks in the adjustment set are stretched by one additional base clock period. A binary pattern is used to specify the exact bit clocks in the adjustment set that should be stretched. A value of one in the pattern denotes to stretch the bit clock while a zero denotes to not stretch the bit clock. The length of the pattern is determined by Y, while the number of ones in the pattern are determined by X. The ones within the pattern are arranged or spread over the length of the pattern as evenly as possible. Each successive bit clock contains either the number of base clocks specified by W or one additional base clock.

For example, assume that an output signal with a free running period of 2000 nanoseconds (nsec.) is desired and that the base clock has a period of 250 nsec. Since the desired period of the output signal is an integral multiple of the period of the base clock signal, the desired output signal may be produced by increasing the base clock by eight times. However, in some cases, the desired period of the output signal is not an integral multiple of the period of the base clock signal and further adjustment needs to be made. For example, assume that an output signal with a free running period of 2050 nsec. is desired and that the base clock has a period of 250 nsec. The desired period of the output signal is 8 and ⅕ times the period of the base clock signal. Therefore, in addition to increasing the base clock by 8 times, further adjustment must be made to produce the desired output signal.

The output signal is adjusted as follows:

The first bit clock is created using 8 base clocks.

The second bit clock is created using 8 base clocks.

The third bit clock is created using 8 base clocks.

The fourth bit clock is created using 8 base clocks.

The fifth bit clock is created using 9 base clocks.

The resultant output signal 108 is shown in FIG. 5 along with the desired output signal 560. As shown, every fifth bit clock of the output signal 108 from the PDDPLL 102 lines up with the desired output signal 560. While the in between bit clocks are slightly off, the errors are predictable and do not vary during any lengths of the free run periods. To produce the output signal shown in FIG. 5, a stretch pattern is used having a binary representation that has five bits and includes a single one, such as 00001, 00010, 00100, etc., which means that one bit clock in five is stretched by an additional base clock.

As a real world example, assume a desired output signal period of 2000 nsec. and a base clock of 122.07 nsec. Dividing the period of the output signal by the period of the base clock yields 16.384. Therefore, the base clock is increased by 16 times. The remainder is approximately 5/13. Therefore, using a pattern that has a length of 13 and contains five ones, such as 0010010010101, will produce a good approximation of the desired 2000 nsec output signal.

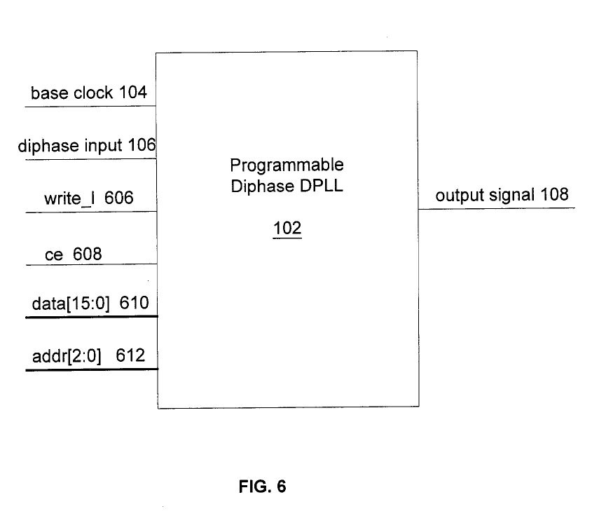

FIGS. 6-9 are schematic diagrams illustrating one implementation of a system with a programmable diphase digital phase lock loop in greater detail. FIG. 6 is a top level diagram of the PDDPLL with inputs 104, 106, 606, 608, 610, and 612 shown on the left and the output 108 shown on the right. In this example, the base clock signal 104 is several times the maximum frequency of the diphase input 106 and is input into the PDDPLL 102 to serve as the system clock. The inputs 606, 608, 610, and 612 are from a microprocessor bus used to configure the PDDPLL 102. The output of the PDDPLL 102 is the bit clock output signal 108.

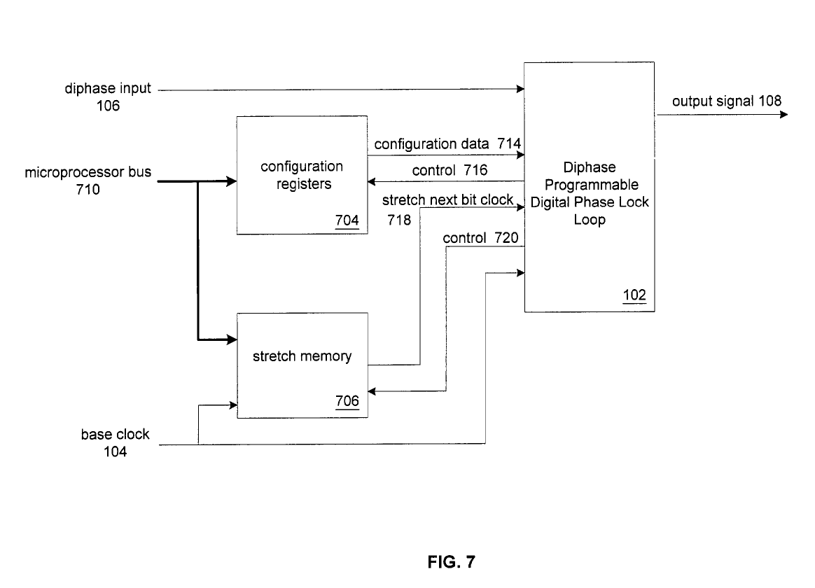

FIG. 7 shows components of the PDDPLL in greater detail according to an implementation of one embodiment of the invention. The configuration registers 704 hold information used to control the operation of the PDDPLL 102. These registers are setup by the microprocessor according to the specification of the diphase input signal 106. The microprocessor also uses a stretch memory 706 to create bit clocks that are not integral multiples of the base clock.

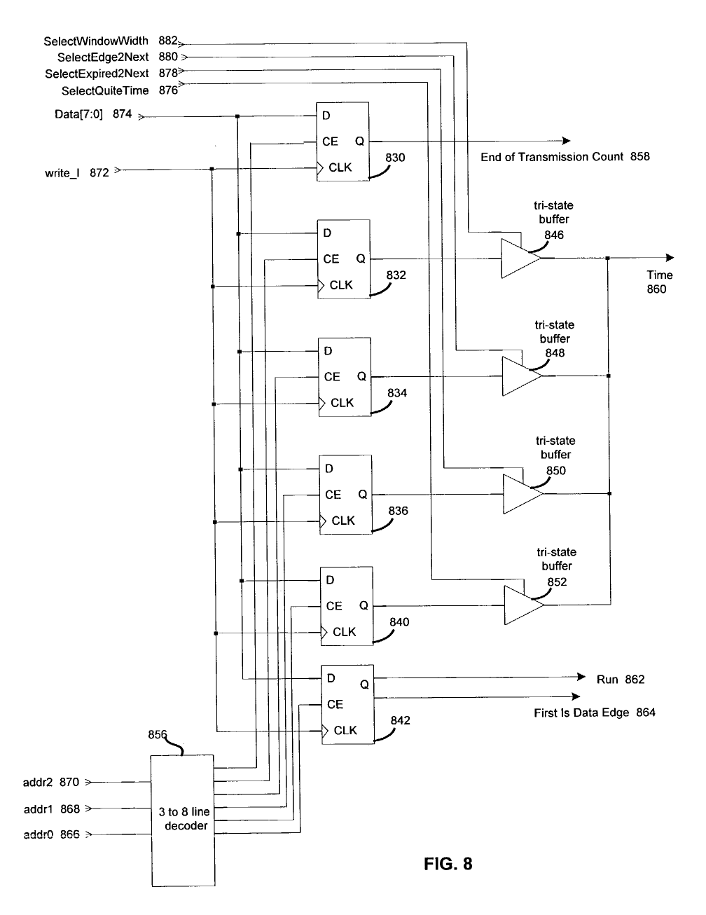

FIG. 8 shows the internals of the configuration registers component according to an implementation of one embodiment of the invention. The decoder 856 takes the three address lines 866, 868, and 870 as input, and outputs five enables that are used to load data into the proper register. When the register's CE signal is asserted, the write_{—}1 signal 872 loads data into the register. The register 830 specifies how many consecutive windows must expire (or how many missing data edges) before an end of packet occurs. The register 832 specifies the width of the window. The register 834 specifies the time from a detected data edge to the start of the next window. The register 836 specifies the time from the end of a maximum window (caused by a missing data edge) to the start of the next window. The register 840 specifies the minimum quiet time. The registers 832, 834, 836, and 840 specify their times in base clock periods. The register 842 is used to specify the first edge in a packet of an intermittent diphase transmission (whether this is a setup or data edge), and to start the component. The values from the registers are then multiplexed into a single time value 860, since the values are not used simultaneously.

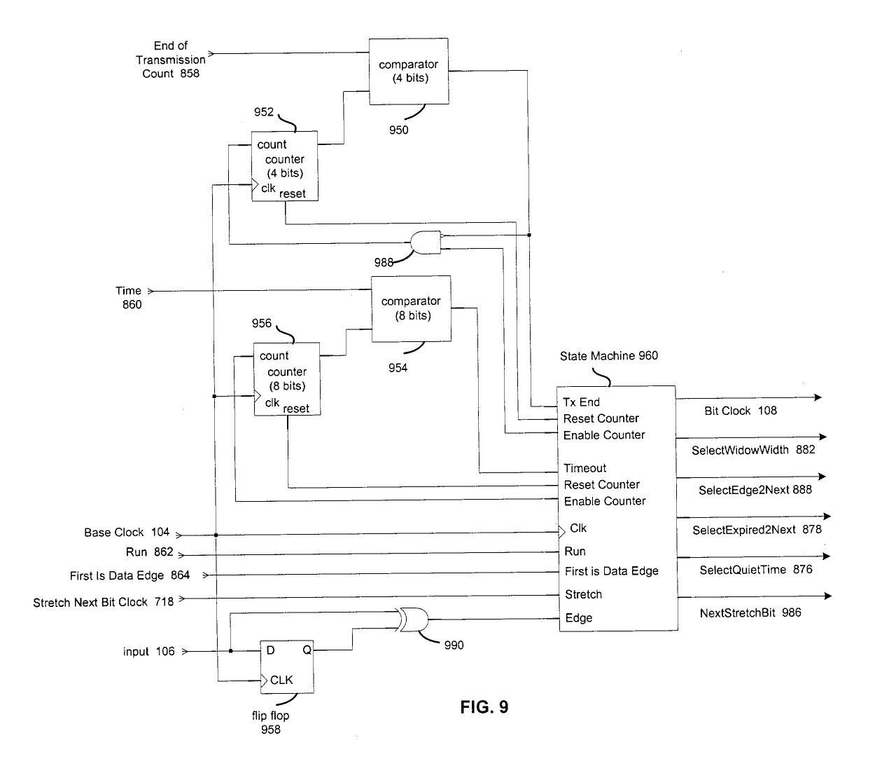

FIG. 9 shows the programmable diphase digital phase lock loop in greater detail according to one embodiment of the invention. The flip flop 958 and XOR gate 990 detect falling and rising edges of the input signal. The comparator 950 creates a signal that is asserted when the associated counter 952 matches the configuration value. Likewise, the comparator 954 creates a signal that is asserted when the associated counter 956 matches the configuration value. The comparator 950 and counter 952 are used to count the number of consecutive windows that expire without seeing a data edge. When the counter 952 reaches the programmed value, the output of the comparator 950 is asserted. The AND gate 988 freezes the counter 952 when the output of the comparator 950 is asserted. The comparator 954 and counter 956 are used to perform timing functions.

In one embodiment, a hardware state machine written in Hardware Description Language (HDL) provides the control for the PDDPLL 102. One implementation of the HDL file, using VHDL, for an intermittent diphase signal is as follows:

```
library IEEE;
use IEEE.std_logic_1164.all;
entity HD_DiPhaseDPLL_CTL is
    port (
        Clk: in STD_LOGIC;
        Edge: in STD_LOGIC;
        Run: in STD_LOGIC ;
        TimeOut: in STD_LOGIC;
        Stretch: in STD_LOGIC;
        FirstIsDataEdge: in STD_LOGIC ;
        TxEnd: in STD_LOGIC ;
        ResetTimeoutCounter: out STD_LOGIC;
            EnableTimeoutCounter: out STD_LOGIC;
            ResetEndTxCounter: out STD_LOGIC ;
            EnableEndTxCounter: out STD_LOGIC ;
            SelectWindowWidth: out STD_LOGIC ;
            SelectExpired2Next: out STD_LOGIC ;
            SelectEdge2Next: out STD_LOGIC ;
            SelectQuietTime: out STD_LOGIC ;
        BitClock: out STD_LOGIC ;
        NextStretchBit: out STD_LOGIC -- count enable the pattern
address counter
    );
end HD_DiPhaseDPLL_CTL;
architecture state_machine of HD_DiPhaseDPLL_CTL is
  type StateType is (Quiet_1,
                    Quiet_2,
                    EdgeWait_1,
                EdgeWait_2,
                InitWindow,
                Window,
                LoadRx_ED, -- ED stands for edge detected
                BitTime_ED,
                LoadRx_FR, -- FR stands for free running
                BitTime_FR,
                Stretch_FR,
                WaitForNext) ;
  signal present_state, next_state: StateType ;
begin
  state_comb:
  process(present_state,TimeOut,Edge,Stretch,FirstIsDataEdge)
begin
      case present_state is
        -- find the quiet time
          when Quiet_1 =>
            next_state <= Quiet_2 ;
        when Quiet_2 =>
          if (Edge = ‘1’) then
              next_state <= Quiet_1 ;
            elsif (TimeOut = ‘1’) then
              next_state <= EdgeWait_1 ;
            else
              next_state <=Quiet_2 ;
            end if ;
        -- wait for the edge that starts us off
        when EdgeWait_1 =>
      if (Edge = ‘0’) then -- if no edge keep looping
        next_state <= EdgeWait_1 ;
      elsif (FirstIsDataEdge = ‘1’) then -- first edge denotes data-
edge
        next_state <= LoadRx_ED ;
      else
        next_state <= EdgeWait_2 ; -- first edge denotes setup-
edge
        end if ;
    -- we are at the beginning of a bit time, wait until next edge
which
    -- is data-edge.
    when EdgeWait_2 =>
      if (Edge = ‘0’) then -- if no edge keep looping
        next_state <= EdgeWait_2 ;
      else
        next_state <= LoadRx_ED ; -- now we are at the data-edge
        end if ;
    -- start of the window
    when InitWindow =>
      next_state <= Window ;
    -- center window: wait for an edge or timeout
    when Window =>
      if (Edge = ‘1’) then
        next_state <= LoadRx_ED ;
      elsif (TimeOut = ‘1’) then
        next_state <= LoadRx_FR ;
      else
        next_state <= Window ;
      end if ;
    -- the states ending in ED are executed when we saw an
    -- edge within the center window
    when LoadRx_ED =>
      next_state <= BitTime_ED ;
    when BitTime_ED =>
      next_state <= WaitForNext ;
    when LoadRx_FR =>
      next_state <= BitTime_FR ;
    when BitTime_FR =>
      if (Stretch = ‘1’) then
        next_state <= Stretch_FR ;
      else
        next_state <= WaitForNext ;
      end if ;
    when Stretch_FR =>
      next_state <= WaitForNext ;
    when WaitForNext =>
      if (TimeOut = ‘1’) then
        next_state <= InitWindow ;
      else
        next_state <= WaitForNext ;
      end if ;
    end case ;
  end process state_comb ;
  -- some outputs that are asserted in only a few states
  -- so they can easily be written outside case statement.
  with present_state select
    BitClock <= ‘1’ when BitTime_ED | BitTime_FR ,
            ‘0’ when others ;
  NextStretchBit <= ‘1’ when present_state = BitTime_FR else ‘0’ ;
  EnableEndTxCounter <= ‘1’ when present_state =
  BitTime_FR else ‘0’ ;
  with present_state select
    ResetEndTxCounter <= ‘1’ when LoadRx_ED | EdgeWait_2 ,
                ‘0’ when others ;
  with present_state select
    ResetTimeoutCounter <= ‘1’ when Quiet_1 | InitWindow |
    BitTime_ED |
BitTime_FR | Stretch_FR ,
                      ‘0’ when others ;
  EnableTimeOutCounter <= ‘1’ ; -- always enable the timeout counter
  SelectWindowWidth <= ‘1’ when present_state =
  InitWindow else ‘0’ ;
  with present_state select
    SelectExpired2Next <= ‘1’ when BitTime_FR | Stretch_FR ,
            ‘0’ when others ;
  SelectEdge2Next <= ‘1’ when present_state = BitTime_ED else ‘0’ ;
  SelectQuietTime <= ‘1’ when present_state = Quiet_2 else ‘0’ ;
  state_clocked: process(Clk,Run,Edge,TxEnd,FirstIsDataEdge) begin
    if (rising_edge(CLK)) then
    if (Run = ‘0’) then -- reset
      present_state <= EdgeWait_1 ;
    elsif (Edge = ‘1’ and TxEnd = ‘1’ and FirstIsDataEdge = ‘1’) then
-- resync out of free running
      present_state <= LoadRx_ED ;
    elsif (Edge = ‘1’ and TxEnd = ‘1’ and FirstIsDataEdge = ‘0’) then
-- resync out of free running
      present_state <= EdgeWait_2 ;
    else
      present_state <= next_state ;
    end if ;
    end if ;
  end process state_clocked ;
end architecture state_machine ;
```

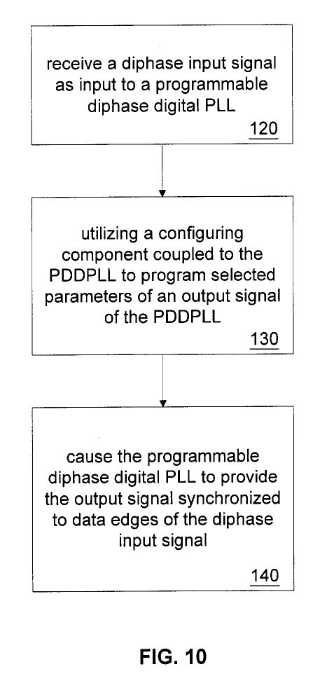

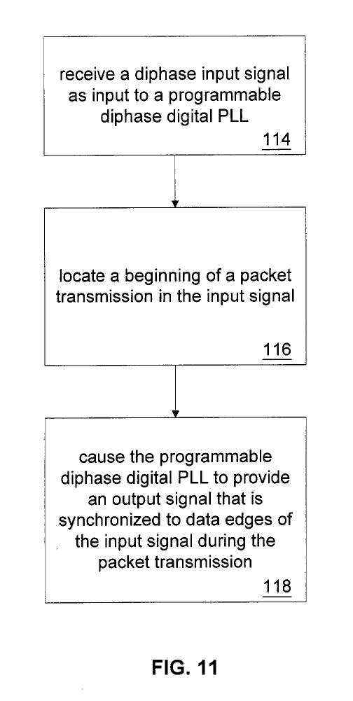

FIG. 10 shows a flow diagram illustrating a method according to an embodiment of the invention. At 120, a diphase input signal is received as input to a PDDPLL. At 130, a configuring component coupled to the PDDPLL is used to program selected parameters of an output signal of the PDDPLL. At 140, the PDDPLL is caused to provide the output signal synchronized to data edges of the diphase input signal. In one embodiment, the PDDPLL is used to provide an output signal that is synchronized to the data edges of the diphase input signal when data edges of the input signal are present, and used to provide an output signal that free runs at a programmed rate when there is an absence of data edges in the input signal. In one embodiment, the free running period of the output signal is adjusted when the free running period of the output signal that is desired is not an integral multiple of the period of the base clock signal.

In one embodiment, the PDDPLL locates two sequential edges of the diphase input signal that are a programmed bit time apart to determine the positions of the data edges of the diphase input signal. In one embodiment, a window is opened that is centered around where the next data edge of the diphase input signal is expected. In one embodiment, the window has a width equal to a maximum expected jitter. In one embodiment, a bit clock is created when a data edge of the diphase input signal is detected within the window. In one embodiment, the window is closed when a data edge of the diphase input signal is detected within the window or when the maximum width of the window is reached.

FIG. 11 shows a flow diagram illustrating a metnod according to an embodiment of the invention. At 114, a diphase input signal is received as input to a PDDPLL. At 116, a beginning of a packet transmission and a data edge associated with the beginning of the packet transmission is located in the diphase input signal. At 118, the PDDPLL is caused to provide an output signal that is synchronized to the data edges of the diphase input signal during the packet transmission. In one embodiment, the PDDPLL is caused to provide an output signal that free runs at a programmed rate during the time between packet transmissions. In one embodiment, the PDDPLL is caused to provide an output signal that free runs at a programmed rate when no data edges are detected in the input signal for a programmed period of time. In one embodiment, the free running period of the output signal is adjusted in the event that the desired free running period of the output signal is not an integral multiple of the period of the base clock signal. In one embodiment, the PDDPLL is caused to resynchronize to the diphase input signal when another packet transmission begins and to provide an output signal that is synchronized to the data edges of the diphase input signal during the other packet transmission.

As will be appreciated by those skilled in the art, the content for implementing an embodiment of the method of the invention, for example, computer program instructions, may be provided by any machine-readable media which can store data that is accessible by system 100, as part of or in addition to memory, including but not limited to cartridges, magnetic cassettes, flash memory cards, digital video disks, random access memories (RAMs), read-only memories (ROMs), and the like. In this regard, the system 100 is equipped to communicate with such machine-readable media in a manner well-known in the art.

It will be further appreciated by those skilled in the art that the content for implementing an embodiment of the method of the invention may be provided to the system 100 from any external device capable of storing the content and communicating the content to the system 100. For example, in one embodiment of the invention, the system 100 may be connected to a network, and the content may be stored on any device in the network.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

What is claimed is:

1. A method comprising:
receiving a diphase input signal as input to a programmable diphase digital phase lock loop (PDDPLL);
utilizing a configuring component coupled to the PDDPLL to program selected parameters of an output signal of the PDDPLL; and
causing the PDDPLL to provide the output signal synchronized to data edges of the diphase input signal.

2. The method of claim 1, further comprising utilizing the PDDPLL to determine positions of data edges of the diphase input signal.

3. The method of claim 2, wherein utilizing the PDDPLL to determine positions of data edges of the diphase input signal comprises utilizing the PDDPLL to locate two sequential edges of the diphase input signal that are approximately a programmed bit time apart to determine positions of data edges of the diphase input signal.

4. The method of claim 1, wherein causing the PDDPLL to provide an output signal comprises causing the PDDPLL to provide an output signal that is synchronized to data edges of the diphase input signal when data edges of the diphase input signal are present, and further comprising utilizing the PDDPLL to provide an output signal that free runs at a programmed rate when there is an absence of any data edges in the diphase input signal for a programmed period of time.

5. The method of claim 1, further comprising opening a time window centered around where the next data edge of the diphase input signal is expected.

6. The method of claim 5, further comprising creating a bit clock when a data edge of the diphase input signal is detected within the window.

7. The method of claim 5, further comprising closing the window when a data edge of the diphase input signal is detected within the window or when a maximum width of the window is reached.

8. The method of claim 1, further comprising adjusting the output signal when a desired free running period of the output signal is not an integral multiple of a period of a base clock signal.

9. An apparatus comprising:
a programmable diphase digital phase lock loop (PDDPLL) having an input to receive a diphase input signal and an output to provide an output signal synchronized with data edges of the diphase input signal; and
a configuring component coupled to the PDDPLL to program selected parameters of the PDDPLL output signal.

10. The apparatus of claim 9, further comprising a clock generator coupled to the PDDPLL to generate a base clock signal for the PDDPLL.

11. The apparatus of claim 10, wherein the PDDPLL comprises an element to adjust the output signal when a desired free running period of the output signal is not an integral multiple of the base clock signal period.

12. The apparatus of claim 9, wherein the PDDPLL having an output comprises the PDDPLL having an output to provide an output signal that is synchronized to the data edges of the diphase input signal when data edges of the diphase input signal are present and to provide an output signal that free runs at a programmed rate when there is an absence of any data edges in the diphase input signal for a programmed period of time.

13. An article of manufacture comprising a machine accessible medium including content that when accessed by a machine causes the machine to:
receive a diphase input signal as input to a programmable diphase digital phase lock loop (PDDPLL);
utilize a configuring component coupled to the PDDPLL to program selected parameters of an output signal of the PDDPLL; and
utilize the PDDPLL to provide the output signal synchronized to the data edges of the diphase input signal.

14. The article of manufacture of claim 13, further comprising a machine accessible medium including content that when accessed by a machine causes the machine to utilize the PDDPLL to locate two sequential edges of the diphase input signal that are approximately a programmed bit time apart to determine positions of data edges of the diphase input signal.

15. The article of manufacture of claim 13, wherein a machine accessible medium including content that when accessed by a machine causes the machine to utilize the PDDPLL to provide an output signal that is synchronized to data edges of the diphase input signal comprises a machine accessible medium comprising content that when accessed by a machine causes the machine to utilize the PDDPLL to provide an output signal that is synchronized to data edges of the diphase input signal when data edges of the diphase input signal are present and to provide an output signal that free runs at a programmed rate when there is an absence of any data edges in the diphase input signal for a programmed period of time.

16. The article of manufacture of claim 13, further comprising a machine accessible medium including content that when accessed by a machine causes the machine to open a time window centered around where the next data edge of the diphase input signal is expected.

17. The article of manufacture of claim 16, further comprising a machine accessible medium including content that when accessed by a machine causes the machine to close the window when a data edge of the diphase input signal is detected within the window or when a maximum width of the window is reached.

18. The article of manufacture of claim 13, further comprising a machine accessible medium including content that when accessed by a machine causes the machine to adjust the output signal when a desired free running period of the output signal is not an integral multiple of a period of a base clock signal of the PDDPLL.

19. A method comprising:
receiving a diphase input signal as input to a programmable diphase digital phase lock loop (PDDPLL);
locating a beginning of a packet transmission and one or more data edges associated with the beginning of the packet transmission in the diphase input signal;
causing the PDDPLL to provide an output signal that is synchronized to the data edges of the diphase input signal during the packet transmission.

20. The method of claim 19, further comprising utilizing a configuring component coupled to the PDDPLL to program selected parameters of the output signal.

21. The method of claim 19, further comprising causing the PDDPLL to provide an output signal that free runs at a programmed rate during the time between packet transmissions.

22. The method of claim 19, further comprising causing the PDDPLL to provide an output signal that free runs at a programmed rate when no data edges are detected in the input signal for a programmed period of time.

23. The method of claim 22, further comprising causing the PDDPLL to resynchronize to the diphase input signal when another packet transmission begins and to provide an output signal that is synchronized to the data edges of the diphase input signal during the other packet transmission.

24. The method of claim 19, further comprising adjusting the output signal when a desired free running period of the output signal is not an integral multiple of a period of a base clock signal of the PDDPLL.

25. A telephony network comprising:
a telephony switch;
an analog/digital converter coupled to the telephony switch;
a programmable diphase digital phase lock loop (PDDPLL) coupled to the analog/digital converter having an input to receive a diphase input signal and having an output to provide a PDDPLL output signal synchronized to data edges of the diphase input signal;
a microprocessor coupled to the PDDPLL via a bus;
a receive component coupled to the microprocessor to receive the diphase input signal and the PDDPLL output signal and to convert serial data from the diphase input signal into parallel data for the microprocessor; and
a transmit component coupled to the microprocessor and the analog/digital converter to receive the PDDPLL output signal and to convert parallel data from the microprocessor to serial data for transmission to the telephony switch via the analog/digital converter.

26. The telephony network of claim 25, wherein the PDDPLL having an output comprises the PDDPLL having an output to provide an output signal that is synchronized to the data edges of the diphase input signal when data edges of the diphase input signal are present and to provide an output signal that free runs at a programmed rate when there is an absence of any data edges in the diphase input signal for a programmed period of time.

27. The telephony network of claim 25, wherein the PDDPLL having an output to provide a PDDPLL output signal comprises the PDDPLL having an output to provide a PDDPLL output signal synchronized to data edges of the diphase input signal to provide the receive component with information on the times at which data can be extracted from the diphase input signal.

28. The telephony network of claim 25, wherein the PDDPLL having an output to provide a PDDPLL output signal comprises the PDDPLL having an output to provide a PDDPLL output signal synchronized to data edges of the diphase input signal to provide the transmit component with information on the rate at which data can be transmitted to the telephony switch.
